(19) United States
(12) Patent Application Publication
(10) Pub. No.: US 2006/0220077 A1
(43) Pub. Date: Oct. 5, 2006

(54) Display device with built-in sensor

(76) Inventors: Hirotaka Hayashi, Fukaya-shi (JP); Takashi Nakamura, Saitama-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/359,407

(22) Filed: Feb. 23, 2006

(30) Foreign Application Priority Data
Mar. 4, 2005 (JP) 2005-060306

(51) Int. Cl. H01L 31/113

(52) U.S. Cl. 257/291

(57) ABSTRACT

A drive circuit that can cover a possible dispersion in characteristics among optical sensors is constructed in order to obtain a stable sensor output. The device includes an optical sensor provided in each of pixels arranged in lines in vertical and horizontal directions, a circuit that instructs a timing of precharge for the optical sensor, and a circuit that instruct a timing for outputting data of the optical sensor from a respective pixel. The device further comprises means that changes the timing for precharge and the timing for outputting the data each to an arbitrary interval.

### CROSS-REFERENCE TO RELATED APPLICATIONS

This application is based upon and claims the benefit of priority from prior Japanese Patent Application No. 2005-060306, filed Mar. 4, 2005, the entire contents of which are incorporated herein by reference.

### BACKGROUND OF THE INVENTION

1. Field of the Invention

The present invention relates to a flat-panel type display device that employs liquid crystal, light-emitting device and the like, and more specifically, to a sensor-equipped display device with a built-in input sensor.

2. Description of the Related Art

Conventionally, liquid crystal display devices include an array substrate on which signal lines, scanning lines and pixel transistors (for example, thin film transistors: TFTs) are arranged, and a drive circuit that drives the signals lines and scanning lines. Due to the recent progress and development in the technology of the integrated circuit, a processing technique that forms a part of a drive circuit on an array substrate has been realized in practice. With the technique, the weight, thickness and overall size of liquid crystal displays have been reduced, and therefore such displays are widely used as display devices for various types of mobile devices such as mobile phones and notebook-type personal computers.

Here, it should be noted that there have been proposed some liquid crystal display apparatus with an additional function of image capturing in which optoelectric transducing elements are arranged on an array substrate. (See, for example, Jpn. Pat. Appln. KOKAI Publication No. 2001-292276 and Jpn. Pat. Appln. KOKAI Publication No. 2001-339640.)

In a liquid crystal display device equipped with the above-mentioned type of image capturing function, the charge amount on the capacitor connected to the optoelectric transducing element varies in accordance with the amount of light received by the optoelectric transducing element. The image capturing can be realized by detecting the voltage at an end of the capacitor.

Recently, the technique of forming a pixel transistor and a drive circuit on a same glass substrate by the polycrystalline silicon (polysilicon) process has been progressed. Therefore, the optoelectric transducing element mentioned above can be easily formed to be adjacent to each respective pixel transistor by the polysilicon process.

In the case where an optical sensor is formed on an insulating substrate such as of glass using a low-temperature polysilicon processing technique, the dispersion of the characteristics among chips is wide. For this reason, when the sensor is used as a pen-input panel or a touch panel, such products, in some cases, malfunction due to the dispersion of the sensitivity among the sensors.

### BRIEF SUMMARY OF THE INVENTION

An object of the embodiments of the present invention is to provide a display device with a built-in sensor, which can obtain a stable sensor output by constructing a drive circuit that can cover the dispersion of the characteristics among optical sensors.

According to one aspect of this invention, there is provided a display device comprising: an optical sensor provided in each of pixels arranged in lines in vertical and horizontal directions; a circuit that instructs a timing of precharge for the optical sensor; and a circuit that instruct a timing for a pixel to output data of the optical sensor; wherein the device further comprises means that changes the timing of precharge and the timing of outputting the data to an arbitrary interval.

Additional objects and advantages of the invention will be set forth in the description which follows, and in part will be obvious from the description, or may be leaned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is an explanatory diagram schematically illustrating a structure of a display device with a built-in input sensor to which the present invention is applied;

FIG. 2 is an explanatory diagram illustrating an example of the structure of an optical sensor according to the present invention;

FIG. 3 is an explanatory diagram illustrating a block structure that constitutes a main portion of the present invention;

FIG. 4 is an explanatory diagram illustrating a block structure that constitutes a main portion of the present invention, which shows a pixel circuit and a sensor circuit in detail;

FIG. 5 is a timing chart based on frame time, illustrating an example of operation of the device according to the present invention;

FIG. 6 is a block diagram illustrating another example of the device according to the present invention;

FIG. 7 is a circuit diagram specifically illustrating one circuit on one side of Y drives shown in FIG. 6;

FIG. 8 is a circuit diagram specifically illustrating one circuit on the other side of the Y drives shown in FIG. 6;

FIG. 9 is a circuit diagram specifically illustrating an example of a sensor output circuit in the device of the present invention; and

FIG. 10 is a timing chart illustrating an example of overall operation of the device according to the present invention.

### DETAILED DESCRIPTION OF THE INVENTION

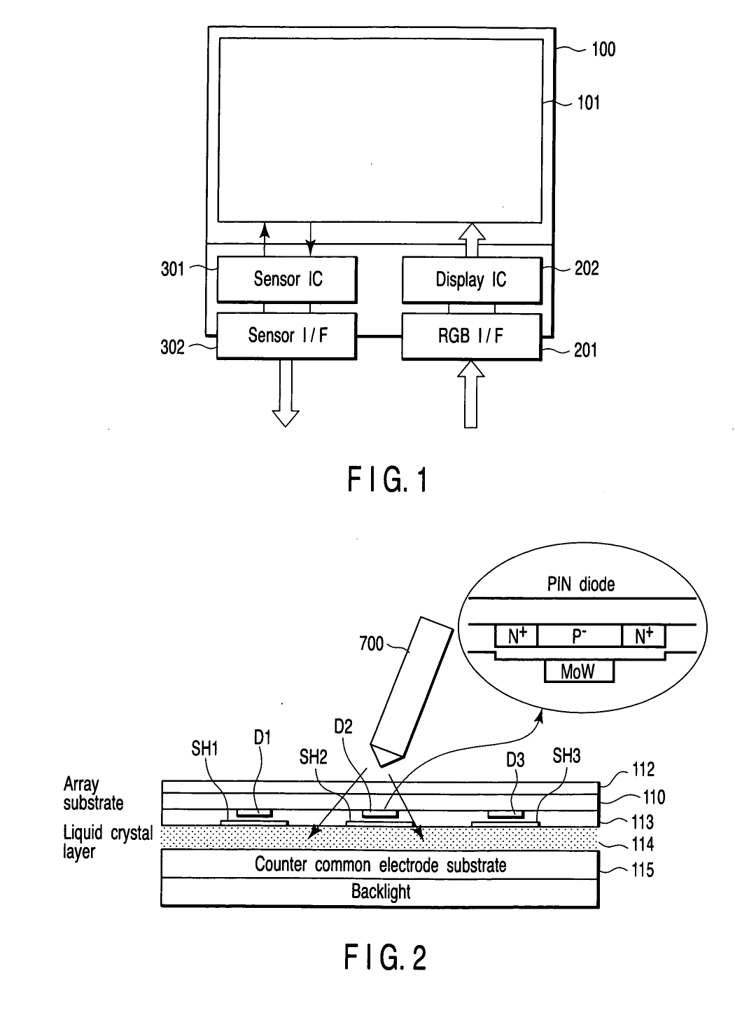

Embodiments of the present invention will now be described with reference to accompanying drawings. FIG. 1 schematically illustrates a built-in sensor type display device 100 according to the present invention. The built-in sensor type display device 100 has a display region 101 which includes a glass substrate. On a back side of the glass substrate, display pixel circuits that are arranged in a two-dimensional manner and sensor circuits that are arranged in a two-dimensional manner are arranged as will be described.

A display image signal output from an image output circuit is input to a display IC 202 via an RGB interface 201. The display IC 202 includes a signal line drive circuit, a pixel gate drive circuit, etc., and it supplies a display image signal to the display image circuit.

The sensor output image signal read from the sensor circuit is read out by the sensor IS 301, and it is guided to an image processing unit via a sensor interface 302.

FIG. 2 illustrates a cross section of a part of the built-in sensor type display device 100, and presents an example of a pin diode that constitutes, in particular, a sensor circuit. Light is input to the array substitute 110 with use of a light pen 700. For protection of the glass, a transparent film 112 is coated on or attached to an outer surface side of the array substrate (glass substrate) 110. On an inner surface side of the array substrate 110, a plurality of scanning lines X, a plurality of signals lines Y, pixel circuits and sensor circuits, which are not illustrated in this figure, are formed using a printing technique and deposition technique. PIN diodes D1, D2 and D3 formed on the inner surface side of the array substrate 110 each function as a light sensitive element within a respective sensor circuit. The PIN diodes D1, D2 and D3 are surrounded by an insulating layer 113. Further, light shielding films SH1, SH2 and SH3 are formed in opposition to the PIN diodes D1, D2 and D3, respectively.

A counter substrate 105 is arranged with a distance from the array substrate 110. The counter substrate 105 has a common electrode (transparent electrode) and is set to face the array substrate 110. A liquid crystal layer 114 is held between the array substrate 110 and the counter substrate 115. A backlight 116 is arranged on the outer surface side of the counter substrate 105. The transmission state of light emitted from the backlight 116 is controlled to form an image on the display screen when the light transmits through the counter substrate 115, liquid crystal layer 114 and array substrate 110.

When light is irradiated onto a PIN diode from the light pen, a current flows in the PIN diode and thus the potential at a terminal of a precharge capacitor (, which will be explained later) changes. Here, as the terminal potential of the precharge capacitor is read out, it is possible to judge whether or not there has been an input. This example presents an inputting method with use of a light pen; however, the present invention may employ a touch panel mode. That is, for example, as the screen is touched with a finger or the like, the light emitted from the backlight is reflected by the finger touch, and the reflection light is irradiated onto the PIN diode. Then, in a similar manner to the above, a current flows in the PIN diode, and the potential at the terminal of the precharge capacitor (, which will be explained later) changes.

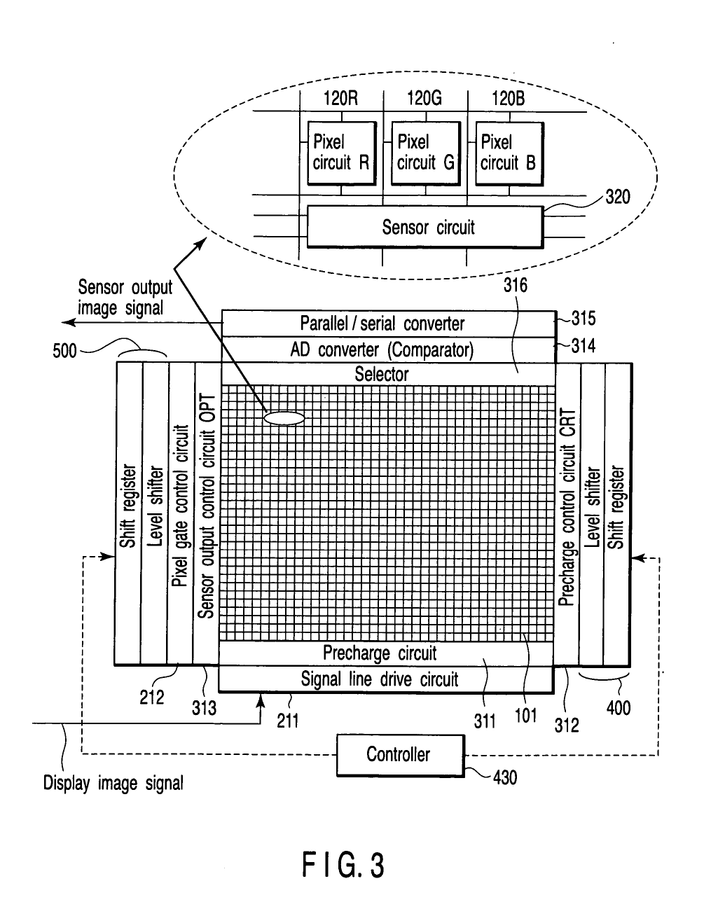

FIG. 3 shows a block diagram that illustrates the structural part characteristic to the built-in sensor type display device according to the present invention. Although the specific operational functions of the characteristic part will be described later, this embodiment describes an example in which the drive means for the sensor circuits are divided into groups, and they are provided on the left and right edge portions of the display region 101 to be driven independently (a precharge control circuit 312 and a sensor output control circuit 313). With this arrangement, the exposure time for the sensor circuit can be arbitrarily adjusted. It should be noted that the circuits may be arranged in reverse right to left or vise versa. Further, a selector 316 is provided as means for reading a sensor output from the display region 101. With this arrangement, the interval between read regions or read positions can be arbitrarily controlled to same the consumption power since outputs from all sensor circuits are not necessarily required at all times.

The basic structure is that an optical sensor is provided in each of the pixels arranged in lines in horizontal and vertical directions. In FIG. 3, a range that is enclosed by the dotted line indicates, for example, one pixel. An optical sensor includes a sensor circuit 320. Next, there is a circuit that instructs a precharge timing for the optical sensor. This circuit includes a precharge control circuit 312 and a precharge control signal line, etc. Further, there is a circuit that instructs a timing of outputting data of an optical sensor from the pixel. This circuit includes a sensor output control circuit 313 and a sensor output control signal line, and further includes means for changing the time for precharge and the time for outputting data to arbitrary intervals. This means includes a shift register and its control circuit.

First, the display control system will be explained. A display image signal is supplied to a signal line drive circuit 211. There are, for example, red (R), green (G) and blue (B) signals as the display image signal. The pixel gate control circuit 212 serially selects scanning lines by scanning signals (pixel circuit scanning signals). This circuit charges a display image signal from the signal line drive circuit 211 to the capacitor of an image circuit formed on a predetermined scanning line (row). (This operation may be called image writing.) In accordance with the potential charged to the capacitor, the light transmission amount of the liquid crystal layer is controlled to change the brightness of the display unit when viewed from a front side.

Next, the sensor control system will be explained. The sensor circuit 320 includes a precharge capacitor and a PIN diode connected in parallel with the capacitor. The precharge circuit 311 outputs a precharge voltage to the precharge capacitor. With regard to the capacitor of a scanning line (row) to be selected for precharge, an appropriate scanning line is selected in accordance with the scanning line (sensor circuit scanning signal) from the precharge control circuit 312. The PIN diode, when sensing light, discharges the charge on the precharge capacitor. Here, the amount discharge corresponds to the amount of light sensed. Those capacitors that are not irradiated with light are not discharged.

After the exposure time elapses, the potential of the precharge capacitor is read out under the control of the sensor output control circuit 313, and the read potential is digitized (into binary data) by an AD converter (, which may be called comparator as well)

314. Then, the binary data are converted via a parallel serial converter 315 into serial data, which are read as sensor output image signals. In this embodiment, a selector 316 is provided to select a sensor output signal read out from the display region 101 and introduce the signal to the AD converter 314.

A shift register and level shifter 400 is illustrate on a right-hand side of the display region, whereas a shift register and level shifter 500 is illustrate on a left-hand side of the display region. The shift register and level shifter 400 are circuits that set the scanning signal output from the precharge control circuit 312 at an appropriate timing and level in synchronism with a vertical synchronous signal and horizontal synchronous signal of the display device. On the other hand, the shift register and level shifter 500 are circuits that set the gate control signal (pixel circuit scanning signal) output from the pixel gate control circuit 212 and the sensor output control signal (sensor circuit scanning signal) output from the sensor output control circuit 313 at an appropriate timing and level in synchronism with a vertical synchronous signal and horizontal synchronous signal of the display device. In this example, one sensor circuit is associated with each of the pixel circuits of R, G and B.

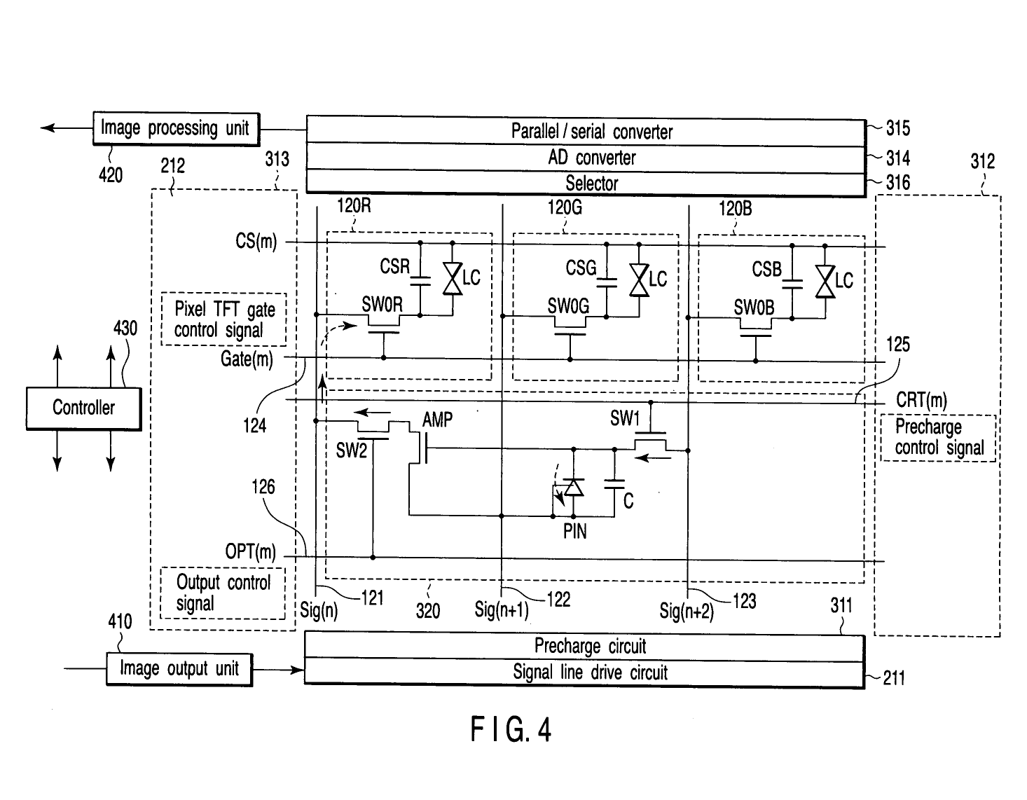

FIG. 4 illustrates a further detailed circuit structure that extracts a group of pixel circuits 120R, 120G, 120B and a sensor circuit 320 shown in the structural diagram of FIG. 3.

First, the display system will be described. An image output unit 410 supplies a display image signal to a signal line drive circuit 211. The signal line drive circuit 211 outputs signals Sig(n), Sig(n+1) and Sig(n+2) to signals lines 121, 122 and 123, respectively. When the signals Sig(n), Sig(n+1) and Sig(n+2) are those associated with pixel circuits 120R, 120G and 120B, respectively, they are judged as pixel circuit scanning signals, and the pixel gate control circuit 212 outputs a pixel TFT control signal Gate(m) to a scanning line 124. Accordingly, TFT switches SWOR, SWOG and SWOB of the respective pixel circuits 120R, 120G and 120B are closed for conduction and thus the signals Sig(n), Sig(n+1) and Sig(n+2) are charged to respective capacitors CSR, CSG and CSB. A CS(m) is a common electrode on the counter substrate side, and a certain potential is applied thereto. The light transmission amount of the liquid crystal in each of the pixel circuits 120R, 120G and 120B is controlled in accordance with the charge amount of the respective one of the capacitors CSR, CSG and CSB.

In the sensor system, three signal lines 121, 122 and 123 are used effectively. The precharge control circuit 312 outputs a precharge control signal CRT(m) to a scanning line 125 (precharge control signal line) to close a switch SW1 of the sensor circuit 320 for conduction. In this manner, the precharge circuit 311 outputs a precharge voltage to the signal line 123. As a result, a capacitor C of the sensor circuit 320 is pre-charged. After the precharge period, the operation shifts to the exposure period. When a current flow occurs in the capacitor C and the PIN diode connected in parallel during the exposure period, the terminal potential of the capacitor C is decreased. In other words, when light is irradiated from the light pen to the PIN diode, a current flow occurs in the PIN diode and therefore the charge of the capacitor C is discharged. When the light of not irradiated, the terminal potential of the capacitor C does not change.

Next, during the read period of the potential of the capacitor C, the sensor output control circuit 313 outputs an output control signal to a scanning line (output control signal line) 126. Thus, the switch SW2 is turned on. During this operation, the terminal potential of the capacitor C appears at a signal line 121 via an amplifier (AMP) and the switch SW2. This output signal is selected by the selector 316 and converted into a binary value by the AD converter 314. The digitized sensor output is captured as a sensor output image signal by an image processing unit 420 via a parallel-serial converter 315.

The controller 430 controls the operation timings for the image output unit 410 and the image processing unit 420, and further for those of the shift registers and level shifters 400 and 500, the image gate circuit 212, the precharge control circuit 312, the sensor output control circuit 313, etc., which belong to a Y drive. Further, the controller 430 controls the operation timings for the signal line drive circuit, the precharge control circuit 311, the selector 316, the AD converter 314, the parallel-serial converter 315, etc., which belong to an X drive.

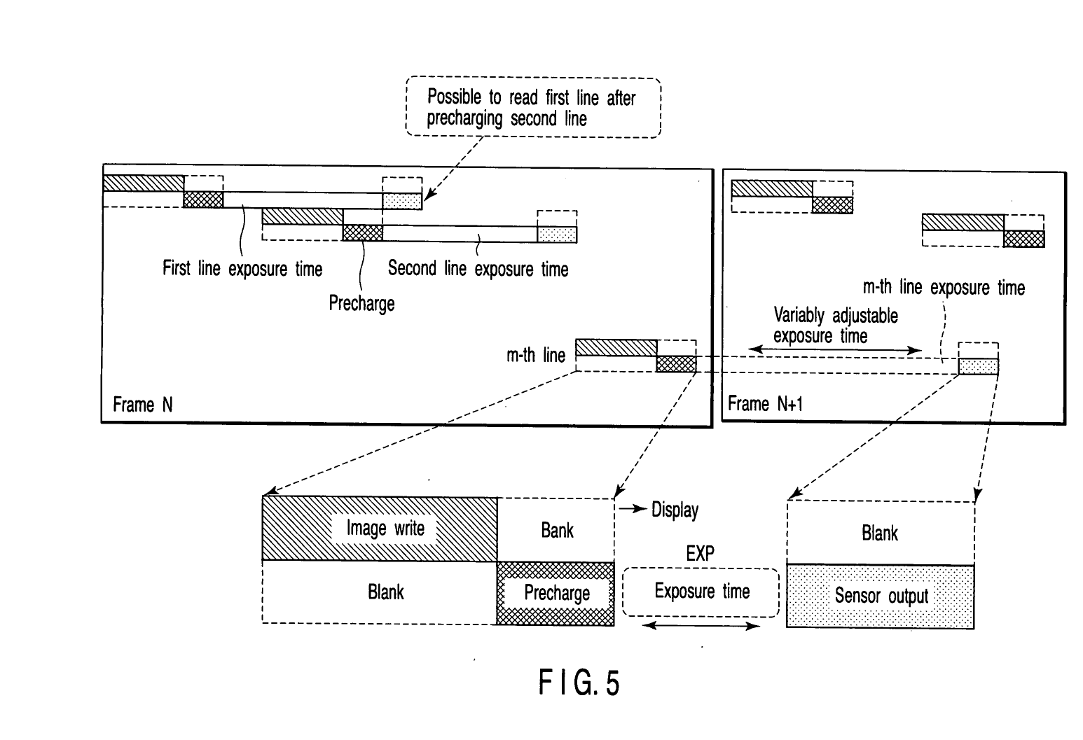

FIG. 5 is an explanatory diagram illustrating the operation timings for the display system and sensor system. As described above, the display system and sensor system share the signal lines 121, 122 and 123 in common in order to avoid the complexity of the circuit structure as well as to facilitate the manufacture thereof. Therefore, the allocation of the operation period is required for the display system and sensor system in order to avoid the collision of signals (display signal and sensor output signal) with each other on a signal line. Further, it should be added here that it is necessary to devise schemes to cancel the dispersion in characteristics between chips by enabling the adjustment of the exposure time of the sensor circuit, which is an object of the present invention.

For the above-described reason, an image write period to the pixel circuit and a precharge period to the sensor circuit are set during a blanking period of one horizontal period on an m-th line in a frame. Meanwhile, in some other blanking period, a read-out period from the sensor circuit is set. The read-out period is set at a period that does not overlap the image write period or the precharge period in a blanking period in one horizontal period of an (m+n)-th line (where n is a number equal to 1 or more but p or less, and p is a value smaller than the number of lines of one frame). Therefore, the exposure time (EXP) of the sensor circuit is expressed as follows, that is, EXP=(m+n)−(m). As a result, when n is set variable as 0, 1, 2, 3, . . . , the exposure time (EXP) can be arbitrarily manipulated.

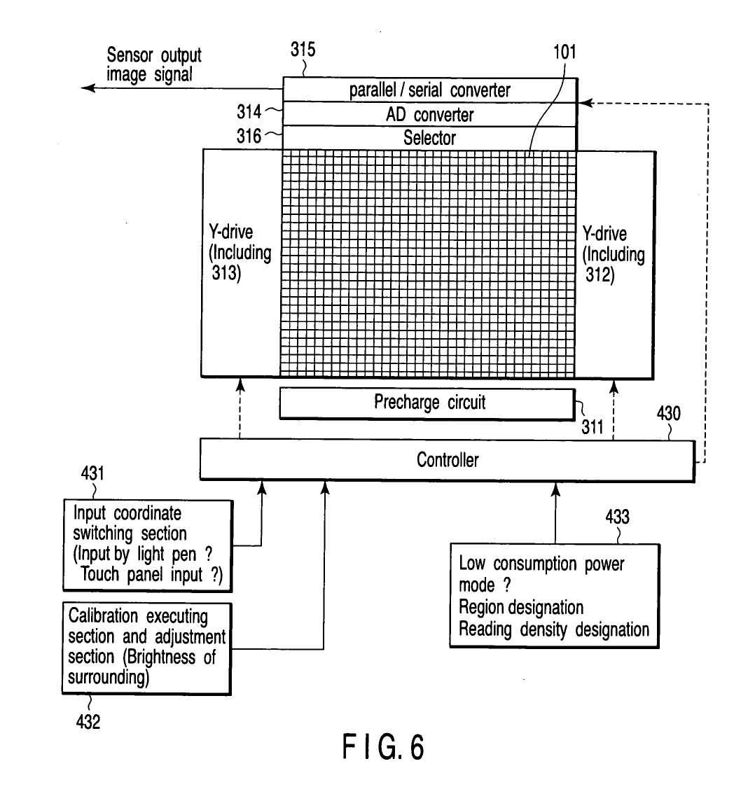

FIG. 6 illustrated an extracted circuit block related to the above-described sensor system. More specifically, a Y drive that includes the precharge control circuit 312 is placed, for example, on a right-hand edge of the display region 101 and a Y drive that includes the sensor output control circuit 313 is placed on a left-hand side edge. Further, the precharge circuit 311 is arranged in a lower edge of the display region 101, whereas the selector 316, the AD converter 314 and the parallel serial converter 315, that form an output selection control unit, are arranged in an upper edge.

It should be noted here that the controller 430 can vary the value of n in reply to an operational input from, for example, an exposure time adjusting circuit.

For example, an input coordinate switching unit 431 is provided as the exposure time adjusting circuit. When a pen light input mode is designated with the input coordination switching unit 431, the value of n is reduced, whereas when a touch input mode is selected, the value of n is increased. This is because in the case of the pen light input mode, the light from the pen is irradiated accurately onto the photo diode, and therefore the light detection is reliably obtained even for a very short exposure time. On the other hand, in the case of the touch input, the light of the backlight is reflected on a finger tip and thus the reflection light is irradiated onto the photodiode. Therefore, in this case, it is preferable that the exposure time should prolonged.

In the meantime, a calibration executing unit and adjustment unit 432 may be provided as the exposure time adjusting circuit. For example, when a calibration is executed while a sheet of white paper is placed on the display region 101, the liquid crystal is driven at a certain potential. Then, the light from the backlight reflects from the white paper, and thus the output level of each sensor circuit is measured. Here, the value of n is changed in accordance with the intensity of the output level with respect to the reference value, and set to such a value that substantially the same output as the reference value can be obtained.

Further, it is alternatively possible to provide an operation unit 433 that sets a low-consumption power mode. For the low-consumption power mode, there are two ways, one is to designate a region, and the other is to designate a reading density. The region designation is effective for such a case where the region of the light input unit is specified, for example, as a left half or a right half of the region. That is, reading outputs from those sensor circuits which are located in the region where no light is input is a waste of consumption power by itself. Therefore, the selector 316 is set so as to guide out the outputs of only the sensor circuits that are located in the region where light is input. The reading density designation is effective for such a case where a high resolution is not required as a sensor output image signal. In such a case, the selector 316 is set so as to select and guides only the sensor outputs from signal lines of odd number-th positions or of even number-th positions.

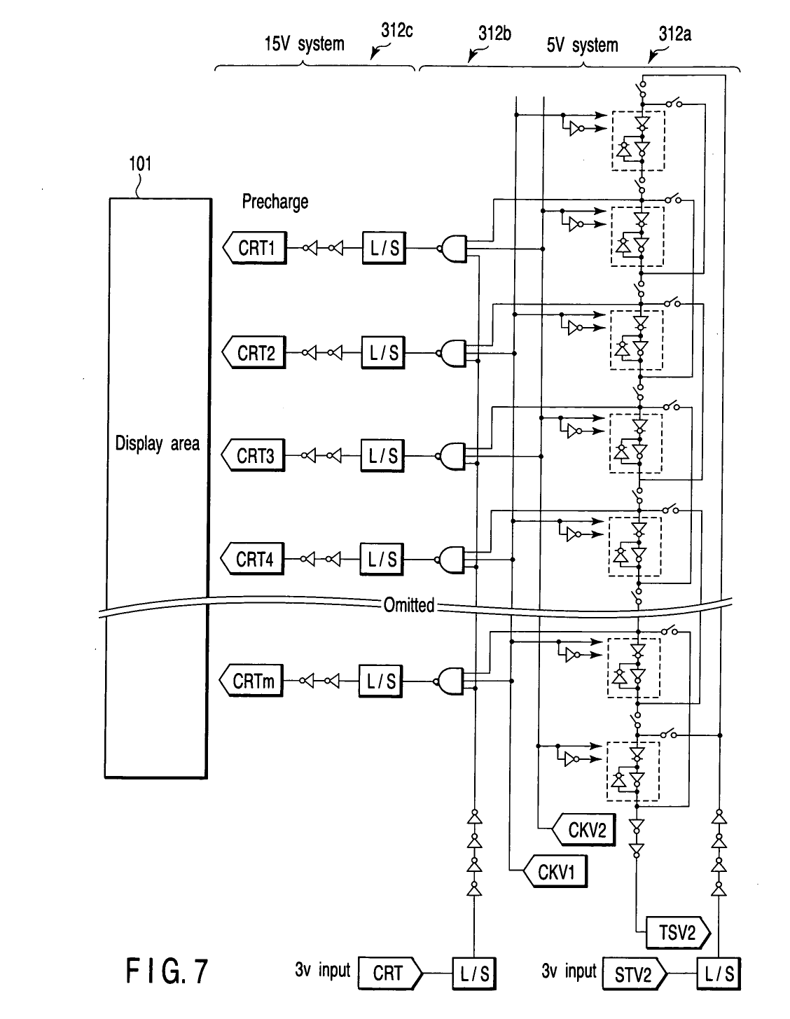

FIG. 7 illustrates a specific structural example of integrated circuitry including the precharge control circuit 312 and the shift-register and level shifter 400. This circuitry includes a shift register section 312a, a selection section 312b that selects an output of each stage of the shift register section 312a, and a level shifter section 312c that sets a signal outputted from the selection section 312b to an appropriate potential.

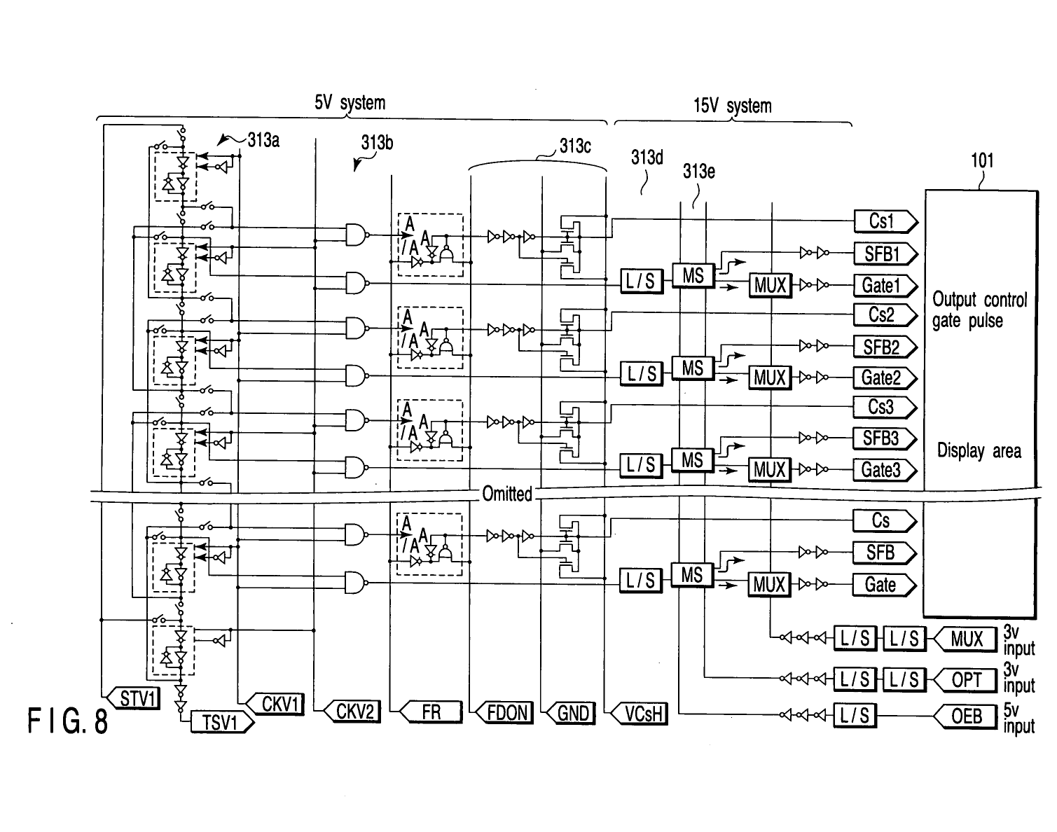

FIG. 8 illustrates a specific structural example of integrated circuitry including the image gate circuit 212, the sensor output control circuit 313, and the shift-register and level shifter 500. The circuit 313 is a shift register, and outputs of each stage of the shift register 313 are selected by a selection circuit 313b. The outputs from the selection circuit 313b are guided to a common electrode applied voltage generating section 313c that supplies the applied voltage to the common element, and a level shifter section 313d. The output from the level shifter 313d is branched off by a branch control section 313e into a pixel TFT gate control signal used in the display system and an output control signal used in the sensor system.

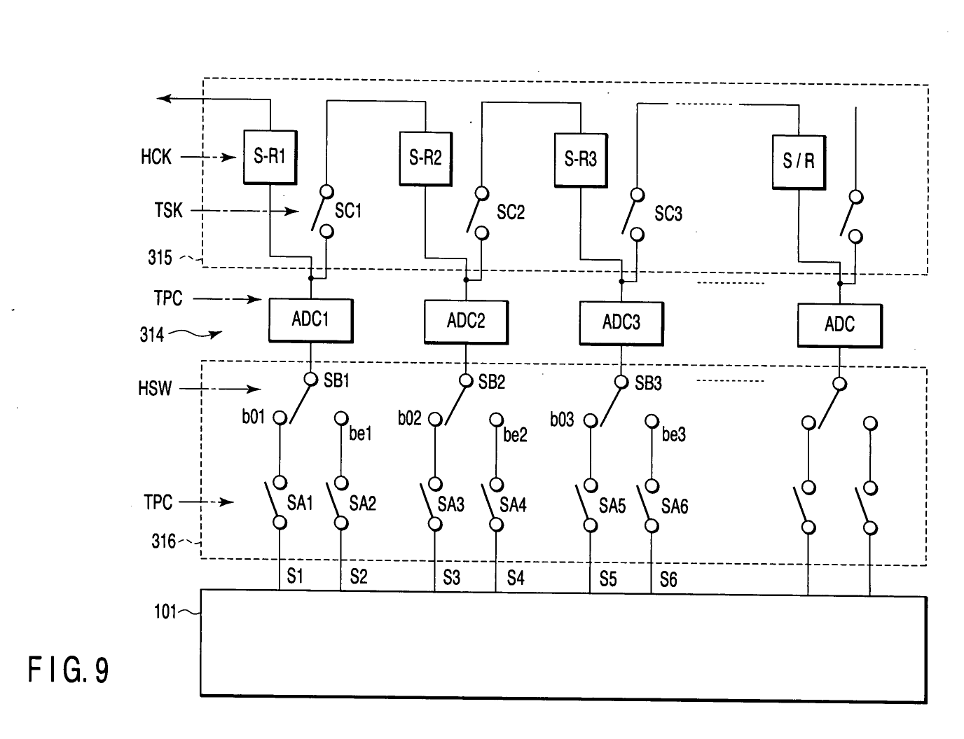

FIG. 9 illustrates an example of the structure in which the selector 316, the AD converter 314 and the parallel serial converter 315 shown in FIG. 6 are arranged. As illustrated in this figure, signal lines S1, S2, S3, . . . from the display region 101 are connected to switches SA1, SA2, SA3, . . . , respectively. Here, for example, switch outputs from odd number-th lines in the column direction, that is, SA1, SA3, SA5, . . . , are connected to those of input terminals on one side, that is, bo1, bo2, bo3, . . . , of switches SB1, SB2, SB3, . . . On the other hand, switch outputs from even number-th lines, that is, SA2, SA4, SA6, . . . , are connected to those of the input terminals on the other side, that is, be1, be2, be3, . . . , of switches SB1, SB2, SB3, . . . .

The outputs from the switches SB1, SB2, SB3, . . . , are input to AD converter circuits AD1, Ad2, AD3, respectively, and the outputs therefrom are compared by a comparator and thus converted into binary data.

Then, the binary data outputs are latched by shift registers S-R1, S-R2, S-R3, . . . . Subsequently, the latched data are serially transferred to the output sides while the switches SC1, SC2, SC#, . . . , are ON.

With the above-described structure, for example, in an odd-number field (or an odd-number frame), data of odd number-th lines of the signal lines are read, and in an even-number field (or an even-number frame), data of even number-th lines of the signal lines are read. In this manner, the consumption power in the shift register 315 can be reduced.

That is, the selector 316 can switch over between such a state that outputs of the odd-number-th lines selected from a plurality of signal lines are used and such a state that outputs of the even-number-th signal lines are used. When an output of a high resolution is desired, the switches SB1, SB2, SB3, . . . are control at a high speed, the outputs of both the odd-number-th signal lines and the even-number-th signal lines are selected. In this case, the shift registers S-R1, S-R2, S-R3, . . . , are each switched in two steps. The shift registers S-R1, S-R2, S-R3, . . . , are each formed to be switchable in one step or two steps.

The structure of the selector 316 is not limited to the above-described configuration. For example, it is alternatively possible that the structure is remodeled to select only the data of the right-half of the region or the left-half of the region. Further, it is possible to extract the data of a column that is particularly designated by selecting a control period for the switches.

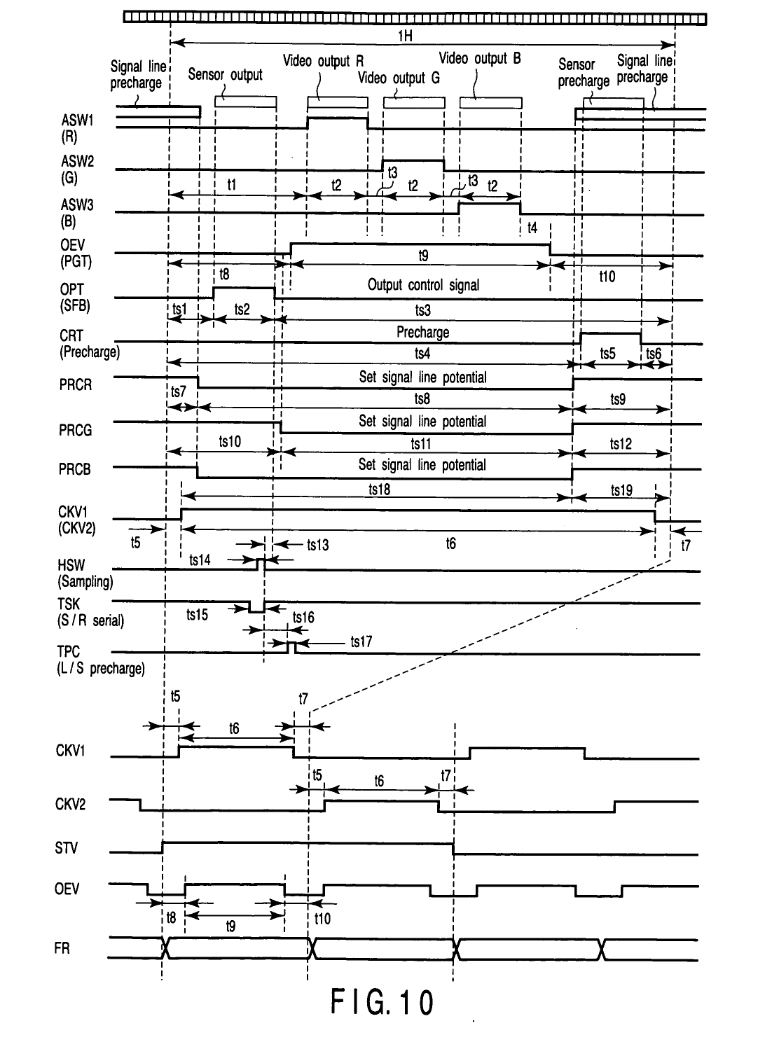

FIG. 10 illustrates examples of signal waves of the sections of the circuits shown in FIGS. 7 to 9. Control signals ASW1, ASW2 and ASW3 shown in FIG. 10 each indicate a write period t2 where each respective signal is written in a respective one of the pixel circuits of R, G and B during the horizontal period. The signals here correspond to Sig(n), Sig(n+1) and Sig(n+2), respectively, with reference to FIG. 4. A control signal OEV (PGT) shown in FIG. 10 is a signal used to generate a pixel TFT gate signal. A control signal OPT (SFB) shown in FIG. 10 is a signal used to set a sensor output period ts2. Further, a control signal CRT is a signal used to set a sensor precharge period ts5. Further, PRCR, PRCG and PRCB are signals that are used to set predetermined potential zones, ts8, ts11 and ts18 for signals lines Sig(n), Sig(n+1) and Sig(n+2), respectively. Control signals CKV1 and CKV2 are signals that are each used to set an operation period of a respective shift register.

HSW, TSK and TPC are control pulses for energy saving measurements when extracting sensor outputs as illustrated in FIG. 9.

It should be noted that the present invention is not limited to the embodiments discussed above directly, but when the invention is carried out in practical usage, it can be remodeled into various versions by changing the structural elements as long as the essence of the invention remains in a scope thereof. Further, various versions can be formed from the invention by combining the structural elements disclosed in the above-described embodiments appropriately. For example, it is also possible that some of the structural elements may be deleted from the all the elements presented in the embodiments. Furthermore, it is possible to combine structural elements from different embodiments together.

As described above, even if there is a dispersion in characteristics among the optical sensors, the dispersion of the characteristics in terms of output signal can be reduced by revising the timing for precharge and the timing for outputting data, thereby making it possible to improve the reliability of the product. The basic idea of the present invention is to include the optical sensor 320 provided in each of the pixels arranged in line in vertical and horizontal directions, a circuit 312 that instructs the precharge timing for the optical sensor and a circuit that instructs the timing for outputting data of the optical sensor from the pixel. Further, the invention includes the means 430 that varies the precharge timing and the timing that outputting the data to arbitrary intervals.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A display device with a built-in sensor, comprising:
an optical sensor provided in each of pixels arranged in lines in vertical and horizontal directions;
a circuit that instructs a timing of precharge for the optical sensor; and
a circuit that instruct a timing for outputting data of the optical sensor from a respective pixel;
wherein the device further comprises means that changes the timing for precharge and the timing for outputting the data each to an arbitrary interval.

2. The display device with built-in sensor, according to claim 1, wherein the circuit that instructs a timing of precharge for the optical sensor;
and the circuit that instruct a timing for outputting data of the optical sensor from a respective pixel, each includes a separate shift register, and either one of the shift registers of two systematic lines is commonly used with a pixel gate output circuit that samples an image signal in a pixel.

3. The display device with built-in sensor, according to claim 2, wherein each of the shift registers of two systematic lines is provided with a circuit that supplies a start pulse thereto independently.

4. A display device with a built-in sensor, comprising:
a plurality of pixel circuits arranged in matrix on an array substrate;
a plurality of sensor circuits arranged in matrix on the array substrate at a ratio of one sensor circuit to a predetermined number of those of the plurality of pixel circuits;
a plurality of signal lines that form a plurality of columns on the array substrate, to charge a display signal to each of the plurality of pixel circuits;
a plurality of scanning lines that form a plurality of rows on the array substrate, to serially select lines of the plurality of pixel circuits;
a plurality of precharge control signal lines that serially turn on the plurality of sensor circuits in unit of row, to precharge a capacitor of each of the plurality of sensor circuits;
a plurality of output control signal lines that serially turn on output amplifiers of the plurality of sensor circuits in unit of row, to detect a voltage of the capacitor of each of the plurality of sensor circuits; and
a precharge control circuit and sensor output control circuit connected independently to the precharge control signal lines and output control signal lines, that sets a start timing for each respective line independently.

5. The display device with built-in sensor, according to claim 4, wherein the precharge control circuits each includes a first shift register that supplies a control signal to the precharge control signal lines, and the sensor output control circuits each includes a second shift register that supplies a control signal to the output control signal lines, and
the display device further comprises an exposure time adjustment circuit that adjust an exposure time by adjusting or switching a timing of the start pulse of each of the first and second shift registers.

6. The display device with built-in sensor, according to claim 5, wherein the exposure time adjustment circuit switches an exposure time to another in accordance with an input with a pen light mode or an input of a touch panel mode.

7. The display device with built-in sensor, according to claim 4, wherein the exposure time adjustment circuit adjusts the exposure time in accordance with execution of calibration and an output from an adjustment section.

8. The display device with built-in sensor, according to claim 4, further comprising a selector that selects part of the outputs of the plurality of sensor circuits.

9. The display device with built-in sensor, according to claim 4, further comprising a selector that selects part of the outputs of the plurality of sensor circuits, wherein the selector switches over between an output selection state in which odd-number-th signal lines of the plurality of signal lines are selected and an output selection state in which even-number-th signal lines of the plurality of signal lines are selected.

10. The display device with built-in sensor, according to claim 4, wherein the sensor circuits are arranged at a ratio of one sensor circuit to R, G and B pixel circuits.
